(19) United States
(12) Patent Application Publication
(10) Pub. No.: US 2015/0047701 A1
(43) Pub. Date: Feb. 19, 2015

(54) SOLAR CELL

(71) Applicant: PANASONIC INTELLECTUAL PROPERTY MANAGEMENT CO. LTD., Osaka (JP)

(72) Inventors: Tatsushi OHYAMA, Gifu (JP); Shigeo YATA, Osaka (JP)

(21) Appl. No.: 14/527,730

(22) Filed: Oct. 29, 2014

Related U.S. Application Data
(63) Continuation of application No. PCT/JP2013/001096, filed on Feb. 26, 2013.

(30) Foreign Application Priority Data
May 30, 2012 (JP) 2012-123303

(51) Int. Cl. H01L 31/0216; H01L 31/077; H01L 31/0224

(52) U.S. Cl. CPC H01L 31/02168; H01L 31/022441; H01L 31/077
USPC 136/256

(57) ABSTRACT

This solar cell is provided with: a substrate, which is a crystalline silicon layer; an intrinsic i-type semiconductor layer, which is directly provided on the light receiving surface side of the substrate; a wide gap layer, which is provided on the i-type semiconductor layer, and which has a p-type or an n-type impurity added thereto; and a transparent conductive layer, which is provided on the wide gap layer. The refractive index of the i-type semiconductor layer has a value between the refractive index of the substrate and that of the transparent conductive layer, and the refractive index of the wide gap layer has a value larger than the refractive index of the transparent conductive layer.

### CROSS-REFERENCE TO RELATED APPLICATION

The present application is a continuation under 35 U.S.C. §120 of PCT/JP2013/001096, filed on Feb. 26, 2013, which is incorporated herein by reference and which claimed priority to Japanese Patent Application No. 2012-123303 filed on May 30, 2012. The present application likewise claims priority under 35 U.S.C. §119 to Japanese Patent Application No. 2012-123303 filed on May 30, 2012, the entire content of which is also incorporated herein by reference.

### TECHNICAL FIELD

The present invention relates to a solar cell.

### BACKGROUND ART

Solar cells using crystalline silicon substrates are widely and commonly put to practical use in solar cell generation systems. Among such solar cells, a structure wherein a thin film of amorphous silicon having a different band gap from that of crystalline silicon is deposited on the crystal surface is referred to as a heterojunction solar cell. Further, a solar cell having a thin intrinsic amorphous silicon layer interposed between a conductive amorphous silicon-based thin film that forms a diffusion potential and a surface of crystalline silicon is known as one of the embodiments of crystalline silicon solar cells with the highest conversion efficiency.

Also, for the purpose of improving photoelectric conversion efficiency, it is a common practice to process one or both sides of the crystalline silicon substrate into a textured structure so as to obtain a high light confinement effect. This textured structure is generally formed by etching using an alkali aqueous solution.

In recent years, there have been higher demands for reducing the thickness of the crystalline silicon substrates used in crystalline silicon solar cells from the aspect of a raw materials issue. Accordingly, due to the raw materials issue, the textured structure etched on crystalline silicon also leads to cost increase, which necessitates a technique for forming the textured structure by another method.

In order to solve this problem, a method for providing an insulating layer having convex-concave geometry on the outermost surface of the crystalline silicon solar cell has been reported.

However, in conventional crystalline silicon solar cells, the difference between the refractive index of the crystalline silicon substrate and the intrinsic amorphous silicon thin film formed on the surface thereof (refractive index of approximately 4) and the refractive index of the insulating layer (refractive index of approximately 1.4 to 1.9) is large. Accordingly, light reflection occurs between the silicon film and the insulating layer, thereby presenting a problem that the power generation efficiency cannot be improved.

The purpose of the present invention is to provide a structure for a crystalline silicon-based solar cell employing a monocrystalline silicon substrate, the structure being capable of reducing a surface reflection by a film forming a heterojunction.

### SUMMARY OF THE INVENTION

According to one aspect of the present invention, a solar cell includes: an electric generation layer which is a crystalline silicon layer; an intrinsic silicon oxide layer provided directly on a light receiving surface side of the electric generation layer; a wide gap layer provided on the silicon oxide layer and having a p-type or an n-type impurity doped thereto; and a transparent conductive layer provided on the wide gap layer, wherein the refractive index of the silicon oxide layer has a value between the refractive index of the electric generation layer and that of the transparent conductive layer, and the refractive index of the wide gap layer has a value larger than the refractive index of the transparent conductive layer.

### BRIEF DESCRIPTION OF DRAWINGS

### Advantageous Effect of the Invention

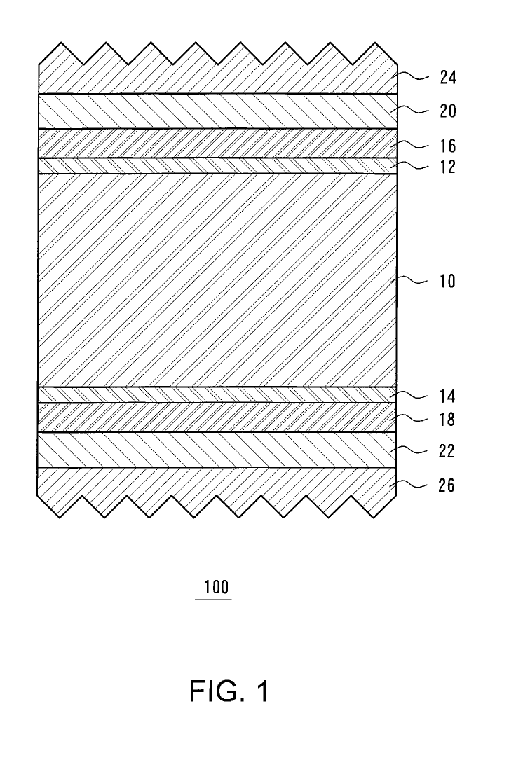

FIG. 1 is a cross-sectional view of a configuration of a solar cell according to a first embodiment.

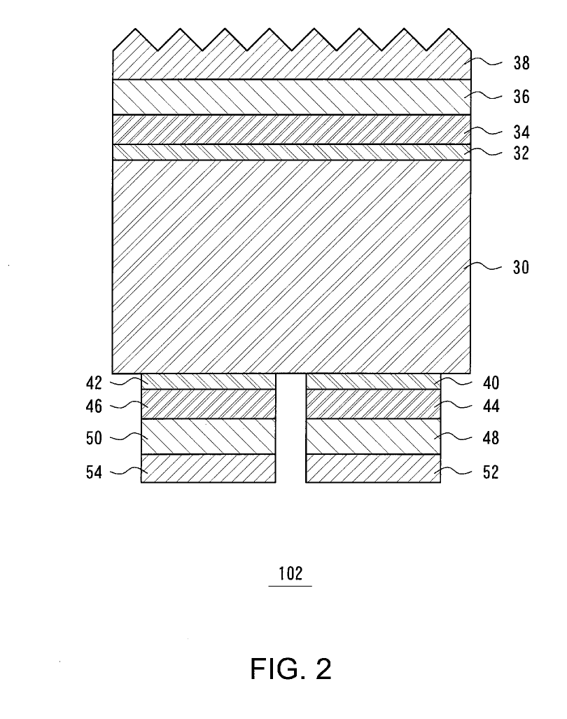

FIG. 2 is a cross-sectional view of a configuration of a solar cell according to a second embodiment.

### DESCRIPTION OF THE PREFERRED EMBODIMENTS

### First Embodiment

A solar cell 100 according to a first embodiment is configured by including a substrate 10, i-type semiconductor layers 12, 14, wide gap layers 16, 18, transparent conductive layers 20, 22, and transparent layers 24, 26, as shown in FIG. 1.

Here, a light receiving surface of the solar cell 100 is on the transparent layer 24 side. The light receiving surface refers to the surface located on the side into which light mostly enters, that is, the surface located on the side into which half or more of light entering the solar cell 100 enters. A back side refers to a side opposite to the light receiving surface.

The substrate 10 is a substrate in the form of a wafer made of an n-type or a p-type conductive crystalline semiconductor. The substrate 10 is a monocrystalline silicon substrate. The substrate 10 servers as an electric generation layer in the solar cell 100, and absorbs incident light to generate electron-hole carrier pairs by a photoelectric conversion effect.

The substrate 10 can be formed by a CZ method, an FZ method, and the like. Preferably, a thickness of the substrate 10 is 100 μm or less. Particularly, if the thickness of the substrate 10 is 50 μm or less, the substrate 10 may be a monocrystalline film formed on an arbitrary substrate by an epitaxial method, or the like. A refractive index of the substrate 10 is approximately 4.1.

The i-type semiconductor layers 12 and 14 are silicon oxide layers obtained by adding a minute amount of oxygen to intrinsic silicon. Specifically, the i-type semiconductor layers 12 and 14 may be, for example, amorphous silicon oxide containing hydrogen. The i-type semiconductor layers 12 and 14 are formed such that a dopant concentration in the film thereof is lower than that of the wide gap layers 16 and 18. For example, preferably, the i-type semiconductor layers 12 and 14 are formed such that the concentration of an n-type or a p-type dopant is 5×10¹⁸/cm³ or less.

The i-type semiconductor layers 12 and 14 are formed respectively on the light receiving side and the back side of the substrate 10. The i-type semiconductor layers 12 and 14 configure a part of passivation layers that cover the surfaces of the substrate 10. A good passivation effect can be obtained by applying silicon oxide over the substrate 10.

Film thicknesses of the i-type semiconductor layers 12 and 14 are preferably made thin so as to control absorption of light as much as possible, while maintaining enough thickness to allow sufficient passivation of the surfaces of the substrate 10. For example, the film thicknesses of the i-type semiconductor layers 12 and 14 are preferably 0.5 nm or more and 10 nm or less.

The wide gap layers 16 and 18 are layers having a wider band gap than crystalline silicon. The wide gap layers 16, 18 are preferably, for example, amorphous silicon layers and silicon oxide layers having a minute amount of oxygen added thereto. Further, the amorphous silicon layer may include a microcrystalline silicon layer. The microcrystalline silicon layer refers to a film of amorphous semiconductor in which crystal grains are precipitated.

The wide gap layer 16 is a layer having a p-type impurity doped thereto. The wide gap layer 16 has a higher concentration of impurities in the film thereof than the i-type semiconductor layer 12. For example, the wide gap layer 16 preferably has a p-type dopant concentration of 1×10^{21/cm}³ or more. The wide gap layer 18 is a layer having an n-type impurity doped thereto. The wide gap layer 18 has a higher concentration of impurities in the film thereof than the i-type semiconductor layer 14. For example, the wide gap layer 18 preferably has an n-type dopant concentration of 1×10²¹/cm³ or more. Further, the wide gap layer 16 may be an n-type layer and the wide gap layer 18 may be a p-type layer.

By applying the amorphous silicon layers doped with impurities as the wide gap layers 16 and 18, the band gap can be made wider with respect to the substrate 10, thereby achieving a good heterojunction configuration with less loss due to absorption of light than the case of applying silicon layers as the wide gap layers 16 and 18. Further, film thicknesses of the wide gap layers 16 and 18 are preferably made thin so as to control absorption of light as much as possible, while maintaining enough thickness to allow an open circuit voltage of the solar cell 100 to be sufficiently high. For example, the film thicknesses of the wide gap layers 16 and 18 are preferably 2 nm or more and 20 nm or less.

The i-type semiconductor layers 12 and 14 and the wide gap layers 16 and 18 can be formed by CVD methods such as a plasma enhanced chemical vapor deposition (PECVD) method. Specifically, the i-type semiconductor layers 12 and 14 can be formed by applying high-frequency electricity to one electrode of parallel plate electrodes to generate plasma of a non-doped source gas that includes silicon-containing gases such as silane (SiH₄) and oxygen-containing gases such as carbon dioxide (CO₂) and oxygen (O₂) and that does not include a p-type and an n-type doping gas, and supplying the plasma to a heated film forming surface of the substrate 10. The plasma of the source gas is generated by supplying high-frequency electricity to a high-frequency electrode from a high-frequency power source while supplying the source gas. Thus, the source is supplied to the surface of the substrate 10 via the plasma to form a silicon oxide layer.

The wide gap layer 16 can be formed by applying high-frequency electricity to an electrode such as a parallel plate electrode to generate plasma of a source gas that includes silicon-containing gases such as silane (SiH₄) and that includes a p-type doping gas such as boron (B₂H₆), and supplying the plasma to a heated film forming surface of the substrate 10. Further, when making the wide gap layer 16 a silicon oxide layer, the source gas may include oxygen-containing gases such as carbon dioxide (CO₂) and oxygen (O₂). At this time, by using a source gas obtained by diluting the silicon-containing gas with hydrogen (H₂), a quality of the film of the wide gap layer 16 formed can be varied depending on a dilution ratio thereof. The wide gap layer 18 can be formed by applying high-frequency electricity to an electrode such as a parallel plate electrode to generate plasma of a source gas that includes silicon-containing gases such as silane (SiH₄) and that includes an n-type doping gas such as phosphine (PH₃), and supplying the plasma to a heated film forming surface of the substrate 10. Further, when making the wide gap layer 18 a silicon oxide layer, the source gas may include oxygen-containing gases such as carbon dioxide (CO₂) and oxygen (O₂). At this time, by using a source gas obtained by diluting the silicon-containing gas with hydrogen (H₂), a quality of the film of the wide gap layer 18 formed can be varied depending on a dilution ratio thereof.

The thicknesses of the i-type semiconductor layers 12 and 14 and the wide gap layers 16 and 18 can be obtained based on measurement results of transmission electron microscope (TEM) observation and secondary ion mass spectrometry (SIMS). In the case where there exists distribution in film thickness, an average film thickness may be taken for the purpose of comparison.

The transparent conductive layers 20 and 22 may employ films made of at least one or a combination of a plurality of transparent conductive oxides (TCO) obtained by doping tin oxide (SnO₂), zinc oxide (ZnO), indium tin oxide (ITO), and the like with tin (Sn), antimony (Sb), fluorine (F), aluminum (Al), and the like. The transparent conductive layers 20 and 22 can be formed, for example, by a sputtering method and an MOCVD method (thermal CVD). The thicknesses of the transparent conductive layers 20 and 22 are preferably 30 nm or more and 300 nm or less. Refractive indices of the transparent conductive layers 20 and 22 are approximately 1.3 or more and 2.0 or less.

The transparent layers 24 and 26 function as antireflection films and as protective films for the light receiving surface of the solar cell 100. The transparent layers 24 and 26 may be either conductive or insulating. The transparent layers 24 and 26 can be, for example, transparent insulating materials such as aluminum oxide, silicon oxide, silicon nitride, and silicon oxynitride, and transparent conductive materials such as tin oxide and indium oxide. The transparent layers 24 and 26 can be formed by a PVD method such as a sputtering method using a target containing the material to be applied, or by a chemical vapor deposition (CVD) method using a gas including an element of the material to be applied.

Thicknesses of the transparent layers 24 and 26 can be, for example, 100 nm or more and 5 μm or less. Also, preferably, a textured structure is provided on the transparent layers 24 and 26. Average values of the heights of convex-concave geometry of the textured structure can be 100 nm or more and 5 μm or less. Refractive indices of the transparent layers 24 and 26 are approximately 1.3 or more and 2.0 or less.

Table 1 shows an example of results illustrating the relationship between a ratio of carbon dioxide (CO₂) to silane (SiH₄) and a refractive index of the i-type semiconductor layers 12 and 14 and the wide gap layers 16 and 18 in the case where the i-type semiconductor layers 12 and 14 and the wide gap layers 16 and 18 are formed by the plasma CVD method. The values of refractive index had been obtained with a light having a wavelength of 550 nm. As shown in Table 1, the refractive indices can be arbitrarily varied between 1.7 and 4.2 by varying the conditions for introducing carbon dioxide (CO₂) when forming a silicon oxide film.

TABLE 1

| | Refractive index n |
|---|---|
| CO₂/SiH₄ ratio | (wavelength: 550 nm) |
| 0 | 4.2 |
| 1 | 2.5 |
| 2 | 2.1 |
| 4 | 1.8 |
| 6 | 1.7 |

Table 2 shows the results of a simulation on surface reflection loss when the refractive indices of the i-type semiconductor layer 12 and the wide gap layer 16 are varied. The rigorous coupled-wave analysis (RCWA) method was used for the simulation. Table 3 shows combinations of the film thickness and the refractive index of the respective layers of a surface geometry model. The width of the convex-concave geometry of the textured structure was 1 μm. The boundary conditions adopted were such that all light that reaches the back side is transmitted. Twenty six wavelengths of incident light, including 300, 340, 380, and 130 nm were set, and the refractive index obtained from the simulation results were converted to current (mA/cm²) generated by the sunlight at an air mass of 1.5, to calculate the surface reflection loss. The smaller the surface reflection loss is, the more light enters the silicon substrate, and as a result, the conversion efficiency of the solar cell becomes high.

TABLE 2

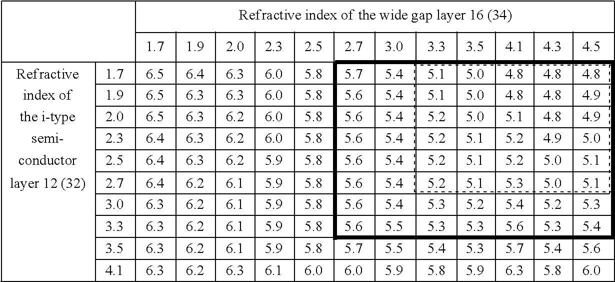

TABLE 3

| | | | Refractive index n |
|---|---|---|---|
| | Film thickness | | (wavelength: 550 nm) |
| Substrate 10 (30) | 50 | μm | 4.1 |
| i-type semiconductor | 5 | nm | 1.7 to 4.1 |
| layer 12 (32) | | | |
| Wide gap layer 16 (34) | 10 | nm | 1.7 to 4.5 |
| Transparent conductive | 100 | nm | 1.9 |
| layer 20 (36) | | | |
| Transparent layer 24 | 260 | nm | 1.5 |

| | |
|---|---|
| (38) | (average film |
| | thickness) |

When the refractive index of the wide gap layer 16 was 1.7 or more and 2.5 or less, which is substantially the same as the refractive index of the transparent conductive layer 20, a difference between the refractive index of the wide gap layer 16 and that of the transparent conductive layer 20 was small, and therefore, there was a large surface reflection loss, 5.8 or more in all cases, regardless of the refractive index of the i-type semiconductor layer 12. Particularly, when the refractive index of the wide gap layer 16 was 1.7, there was a significant surface reflection loss, 6.3 or more.

When the refractive index of the wide gap layer 16 was 2.7 or more and 4.5 or less, the refractive index of the i-type semiconductor layer 12 was 4.1 or more in the case where oxygen was not contained therein, and the surface reflection losses in all cases were high, 5.8 or more. That is, the surface reflection loss could not be sufficiently reduced by varying only the refractive index of the wide gap layer 16 that had been doped with impurities.

On the other hand, by adjusting the oxygen concentration in the i-type semiconductor layer 12 to control the refractive index to 1.7 or more and 3.3 or less (a range surrounded by a bold line in Table 2), low surface reflection loss could be obtained. Particularly, in the range where the refractive indices are 1.7 or more and 2.7 or less (a range surrounded by a dashed line in Table 2), the surface reflection loss could be kept particularly low.

That is, by setting the refractive index of the i-type semiconductor layer 12 to a value between the refractive index of the substrate 10 and that of the transparent conductive layer 20, and setting the refractive index of the wide gap layer 16 to a value larger than the refractive index of the transparent conductive layer 20, an extremely low surface reflection loss and a passivation effect, and a low light absorption loss by the wide gap, are realized. As a result, the conversion efficiency of the solar cell 100 can be improved.

### Second Embodiment

A solar cell 102 according to a second embodiment is configured by including a substrate 30, an i-type semiconductor layer 32, a wide gap layer 34, a transparent conductive layer 36, a transparent layer 38, i-type semiconductor layers 40, 42, a p-type semiconductor layer 44, an n-type semiconductor layer 46, transparent conductive layers 48, 50, and electrode layers 52, 54, as shown in FIG. 2. As shown in FIG. 2, the solar cell 102 is a back contact solar cell in which both electrodes that are to be connected to the p-type and n-type semiconductor layers are provided on the back side of the solar cell 102. Further, the transparent layer 38 is on the light receiving surface side of the solar cell 102.

The substrate 30 is a substrate in the form of a wafer made of an n-type or a p-type conductive crystalline semiconductor. The substrate 30 is a monocrystalline silicon substrate. The substrate 30 servers as an electric generation layer in the solar cell 102, and absorbs incident light to generate electron-hole carrier pairs by a photoelectric conversion effect. The substrate 30, as is the case with the substrate 10, can be formed by a CZ method, an FZ method, and the like. Preferably, a thickness of the substrate 30 is 100 μm or less. Particularly, if the thickness of the substrate 30 is 50 μm or less, the substrate 30 may be a monocrystalline film formed on an arbitrary substrate by an epitaxial method, or the like. A refractive index of the substrate is around 4.1.

The i-type semiconductor layer 32 is a silicon oxide layer obtained by adding a minute amount of oxygen to an intrinsic silicon. Specifically, the i-type semiconductor layer 32 may be, as is the case with the i-type semiconductor layers 12 and 14, amorphous silicon oxide containing hydrogen. The i-type semiconductor layer 32 is formed such that a dopant concentration in the film thereof is lower than that of the wide gap layer 34. For example, preferably, the i-type semiconductor layer 32 is formed such that the concentration of an n-type or a p-type dopant is 5×10¹⁸/cm³ or less. The i-type semiconductor layer 32 is formed on the surface of the light receiving side of the substrate 30. The i-type semiconductor layer 32 constitutes a part of a passivation layer that covers the surface of the substrate 30. A good passivation effect can be obtained by applying silicon oxide over the substrate 30. A film thickness of the i-type semiconductor layer 32 is preferably made thin so as to control absorption of light as much as possible, while maintaining enough thickness to allow sufficient passivation of the surfaces of the substrate 30. For example, the film thickness of the i-type semiconductor layer 32 is preferably 0.5 nm or more and 10 nm or less.

The wide gap layer 34 is a layer having a wider band gap than crystalline silicon. The wide gap layer 34 is, for example, preferably an amorphous silicon layer and a silicon oxide layer having a minute amount of oxygen added thereto. The wide gap layer 34 is a layer having a p-type or an n-type impurity doped thereto. The wide gap layer 34 has a higher concentration of impurities in the film thereof than the i-type semiconductor layer 32. For example, the wide gap layer 34 preferably has a p-type dopant concentration of 1×10²¹/cm³ or more. By applying the amorphous silicon layer doped with impurities as the wide gap layer 34, the band gap can be made wider with respect to the substrate 30, whereby a good heterojunction configuration with less loss due to absorption of light than the case of applying the silicon layer as the wide gap layer 34 can be achieved. Further, a film thickness of the wide gap layer 34 is preferably made thin so as to control absorption of light as much as possible, while maintaining enough thickness to allow sufficient reduction in recombination velocity at the surface of the substrate 30 due to surface electric field. For example, the film thickness of the wide gap layer 34 is preferably 2 nm or more and 20 nm or less.

The transparent conductive layer 36 may employ a film made of at least one or a combination of a plurality of transparent conductive oxides (TCO) obtained by doping tin oxide (SnO₂), zinc oxide (ZnO), indium tin oxide (ITO), and the like with tin (Sn), antimony (Sb), fluorine (F), aluminum (Al), and the like. A thickness of the transparent conductive layer 36 is preferably 30 nm or more and 300 nm or less. A refractive index of the transparent conductive layer 36 is approximately 1.3 or more and 2.0 or less.

The transparent layer 38 functions as an antireflection film and as a protective film for the light receiving surface of the solar cell 102. The transparent layer 38 may be either conductive or insulating. The transparent layer 38 can be, for example, a transparent insulating material such as aluminum oxide, silicon oxide, silicon nitride, and silicon oxynitride, and a transparent conductive material such as tin oxide and indium oxide. A thickness of the transparent layer 38 can be, for example, 100 nm or more and 5 μm or less. Also, preferably, a textured structure is provided on the transparent layer 38. Average values of the heights of convex-concave geometry of the textured structure can be 100 nm or more and 5 μm or less. A refractive index of the transparent layer 38 is approximately 1.3 or more and 2.0 or less.

The i-type semiconductor layers 40 and 42 are intrinsic amorphous silicon layers. Specifically, the i-type semiconductor layers 40 and 42 may be, for example, amorphous silicon containing hydrogen. The i-type semiconductor layers 40 and 42 are formed such that a dopant concentration in the film thereof is lower than that of the p-type semiconductor layers 44 and 46. For example, preferably, the i-type semiconductor layers 40 and 42 are formed such that the concentration of an n-type or a p-type dopant is 5×10¹⁸/cm³ or less. The i-type semiconductor layers 40 and 42 are formed on the surface of the back side of the substrate 30. The i-type semiconductor layers 40 and 42 constitute a part of a passivation layer that covers the back side of the substrate 30. A good passivation effect can be obtained by applying amorphous silicon over the substrate 30. Film thicknesses of the i-type semiconductor layers 40 and 42 are preferably made thin so as to control absorption of light as much as possible, while maintaining enough thickness to allow sufficient passivation of the surfaces of the substrate 30. For example, the film thicknesses of the i-type semiconductor layers 40 and 42 are preferably 0.5 nm or more and 10 nm or less.

The p-type semiconductor layer 44 is a layer having a p-type impurity doped thereto. The p-type semiconductor layer 44 has a higher concentration of impurities in the film thereof than the i-type semiconductor layer 40. For example, the p-type semiconductor layer 44 preferably has a p-type dopant concentration of 1×10²¹/cm³ or more. The n-type semiconductor layer 46 is a layer having an n-type impurity doped thereto. The n-type semiconductor layer 46 has a higher concentration of impurities in the film thereof than the i-type semiconductor layer 42. For example, the n-type semiconductor layer 46 preferably has an n-type dopant concentration of 1×10²¹/cm³ or more. The p-type semiconductor layer 44 and the n-type semiconductor layer 46 are, for example, preferably amorphous silicon layers and silicon oxide layers having a minute amount of oxygen added thereto. Film thicknesses of the p-type semiconductor layer 44 and the n-type semiconductor layer 46 are preferably made thin so as to control absorption of light as much as possible, while maintaining enough thickness to allow an open circuit voltage of the solar cell 102 to be sufficiently high. For example, the film thicknesses of the p-type semiconductor layer 44 and the n-type semiconductor layer 46 are preferably 2 nm or more and 20 nm or less.

The i-type semiconductor layer 32, the wide gap layer 34, the i-type semiconductor layers 40, 42, the p-type semiconductor layer 44 and the n-type semiconductor layer 46 can be formed by CVD methods such as a plasma enhanced chemical vapor deposition (PECVD) method. Specifically, the i-type semiconductor layers 32, 40, 42 can be formed by applying high-frequency electricity to one electrode of parallel plate electrodes to generate plasma of a non-doped source gas that includes silicon-containing gases such as silane (SiH₄) and oxygen-containing gases such as carbon dioxide (CO₂) and oxygen (O₂) and that does not include a p-type and an n-type doping gas, and supplying the plasma to a heated film forming surface of the substrate 30. The plasma of the source gas is generated by supplying high-frequency electricity to a high-frequency electrode from a high-frequency power source while supplying the source gas. Thus, the source is supplied to the surface of the substrate 30 via the plasma to form a silicon oxide layer.

The wide gap layer 34, the p-type semiconductor layer 44 an the n-type semiconductor layer 46 can be formed by applying high-frequency electricity to an electrode such as a parallel plate electrode to generate plasma of a source gas that includes silicon-containing gases such as silane (SiH₄) and that includes a p-type doping gas such as boron (B₂H₆) or an n-type doping gas such as phosphine (PH₃), and supplying the plasma to a heated film forming surface of the substrate 30. Further, when making the wide gap layer 34 a silicon oxide layer, the source gas may include oxygen-containing gases such as carbon dioxide (CO₂) and oxygen (O₂). At this time, by using a source gas obtained by diluting the silicon-containing gas with hydrogen (H₂), a quality of the film of the wide gap layer 34, the p-type semiconductor layer 44 and the n-type semiconductor layer 46 formed can be varied depending on a dilution ratio thereof. The film thicknesses of the i-type semiconductor layer 32, the wide gap layer 34, the i-type semiconductor layers 40, 42, the p-type semiconductor layer 44 and the n-type semiconductor layer 46 can be obtained based on measurement results of transmission electron microscope (TEM) observation and secondary ion mass spectrometry (SIMS). In the case where there exists distribution in film thickness, an average film thickness may be taken for the purpose of comparison.

The transparent conductive layers 48 and 50 may employ films made of at least one or a combination of a plurality of transparent conductive oxides (TCO) obtained by doping tin oxide (SnO₂), zinc oxide (ZnO), indium tin oxide (ITO), and the like with tin (Sn), antimony (Sb), fluorine (F), aluminum (Al), and the like. The transparent conductive layers 48 and 50 can be formed, for example, by a sputtering method and an MOCVD method (thermal CVD). The thicknesses of the transparent conductive layers 48 and 50 are preferably 30 nm or more and 300 nm or less.

The electrode layers 52 and 54 are a p-type electrode portion and an n-type electrode portion for taking out electricity from the p-type semiconductor layer 44 and the n-type semiconductor layer 46, respectively. The electrode layers 52 and 54 may be configured by metals such as silver (Ag), copper (Cu), and aluminum (Al), or materials including alloys thereof. The electrode layers 52 and 54 can be formed by a screen printing method, a sputtering method, a CVD method, a plating method, and the like. The thicknesses of the electrode layers 52 and 54 are preferably 100 nm or more and 5 μm or less.

In the present embodiment as well, similar to the first embodiment, the surface reflection loss can be prevented by optimizing the refractive indices of the substrate 30, the i-type semiconductor layer 32, the wide gap layer 34, the transparent conductive layer 36, and the transparent layer 38. That is, by setting the refractive index of the i-type semiconductor layer 32 to a value between the refractive index of the substrate 30 and that of the transparent conductive layer 36, and setting the refractive index of the wide gap layer 34 to a value larger than the refractive index of the transparent conductive layer 36, an extremely low surface reflection loss and a passivation effect, and a low light absorption loss by the wide gap are realized. As a result, the conversion efficiency of the solar cell 102 can be improved.

While description has been given for the present invention with reference to the abovementioned embodiments, it is obvious that the present invention is not limited to such embodiments whatsoever and that combinations or substitutes of the configurations shown in the embodiments are also encompassed by the scope of the present invention. Further, it is possible to change the combinations and the procedures of the processes shown in the embodiments or to add various modifications, including design changes, to the embodiments based on knowledge of a person skilled in the art, and such modifications of the embodiments are also encompassed by the scope of the present invention.

1. A solar cell, comprising:
an electric generation layer which is a crystalline silicon layer;
a substantially intrinsic silicon oxide layer provided directly on a light receiving surface side of the electric generation layer;
a wide gap layer provided on the silicon oxide layer and having a p-type or an n-type impurity doped thereto; and
a transparent conductive layer provided on the wide gap layer, wherein
a refractive index of the silicon oxide layer has a value between a refractive index of the electric generation layer and that of the transparent conductive layer, and
a refractive index of the wide gap layer has a value larger than the refractive index of the transparent conductive layer.

2. The solar cell according to claim 1, wherein
the solar cell has a back contact structure in which both a p-type electrode and an n-type electrode are provided on a back side of the solar cell on an opposite side to the light receiving side of the electric generation layer.

3. The solar cell according to claim 2, wherein
a transparent layer is provided on the transparent conductive layer, and
a textured structure having convex-concave geometry is not provided on the light receiving side of the electric generation layer, and the textured structure having convex-concave geometry is provided on the transparent layer.
